(19) United States
(12) Patent Application Publication
(10) Pub. No.: US 2017/0153675 A1
(43) Pub. Date: Jun. 1, 2017

(54) FASTENING DEVICE

(71) Applicants: Inventec (Pudong) Technology Corp., Shanghai (CN); Inventec Corporation, Taipei (TW)

(72) Inventors: Yuan-Chang Yang, Taipei (TW); Shih-Wei Chen, Taipei (TW)

(21) Appl. No.: 15/091,555

(22) Filed: Apr. 5, 2016

(30) Foreign Application Priority Data
Nov. 27, 2015 (CN) 201510846732.7

(51) Int. Cl. G06F 1/18; H05K 7/20; H05K 7/14

(52) U.S. Cl. CPC G06F 1/187; H05K 7/1487; H05K 7/20

(57) ABSTRACT

A fastening device for fastening at least one storage device includes a bracket and a cover plate. The bracket has an accommodating space, a first opening and a second opening. The bracket is formed as a hollow rectangular structure and an assembly rail is disposed at opposite inner side walls of the bracket. The at least one storage device is accommodated in the accommodating space through two sides of the assembly rail. The cover plate is disposed on a side of the bracket and covers the first opening of the bracket. The bracket and the cover plate are engaged with each other, such that an appearance of the fastening device conforms to Peripheral Component Interconnect (PCI) standard.

### BACKGROUND OF THE INVENTION

1. Field of the Invention

The invention relates to a fastening device and, more particularly, to a fastening device conforming to Peripheral Component Interconnect (PCI) standard.

2. Description of the Prior Art

As technology advances and develops, computers are considered a necessity by a lot of people in their daily lives. In general, a computer casing or server is usually equipped with a storage device such as hard disk drive (HDD) or solid state drive (SSD) for storing necessary programs and data. So far the aforesaid storage device has to be fastened in the computer casing or server by related fastening structure. When the capacity of the existing storage device is not enough and the number of storage devices has to be expanded, the fastening structure of a new storage device may interfere with other components within the computer casing or server and then the new storage device may not be installed. Consequently, the number of storage devices cannot be expanded.

### SUMMARY OF THE INVENTION

The invention provides a fastening device conforming to Peripheral Component Interconnect (PCI) standard, so as to solve the aforesaid problems.

According to an embodiment of the invention, a fastening device for fastening at least one storage device comprises a bracket and a cover plate. The bracket has an accommodating space, a first opening and a second opening. The bracket is formed as a hollow rectangular structure and an assembly rail is disposed at opposite inner side walls of the bracket. The at least one storage device is accommodated in the accommodating space through two sides of the assembly rail. The cover plate is disposed on a side of the bracket and covers the first opening of the bracket. The bracket and the cover plate are engaged with each other, such that an appearance of the fastening device conforms to Peripheral Component Interconnect (PCI) standard.

Preferably, an outer side wall of the bracket has a connector and the connector is capable of being inserted into a slot conforming to PCI standard.

As mentioned in the above, when the capacity of the existing storage device is not enough and the number of storage devices has to be expanded, a user can place at least one storage device into the bracket of the fastening device of the invention and then insert the connector of the bracket into the slot conforming to PCI standard. Afterward, the user can fasten the cover plate on a casing of a computer or server by screws. Accordingly, the user can install and expand the storage device easily. The bracket of the invention may be made of plastic, such that a short circuit will not occur between the connector of the bracket and the electric contacts of the slot. Furthermore, since the connector of the bracket can be fastened in the slot by an engaging manner, the invention need not use additional device or structure to fasten the fastening device. In general, a mainboard of the computer or server usually has a plurality of PCI expansion slots for installing a plurality of expansion cards such as sound card, graphics card, network card and so on, so as to enhance additional functions. Since the appearance of the fastening device of the invention conforms to PCI standard, the user can use the fastening device of the invention to accommodate at least one storage device to expand the storage device when there is an idle PCI expansion slot in the computer or server. Accordingly, as long as a system supports PCI interface, the fastening device of the invention can be used to expand the storage device. The use of the invention is wide and the assembly process is easy.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating a fastening device according to an embodiment of the invention.

FIG. 2 is a perspective view illustrating the fastening device shown in FIG. 1 from another viewing angle.

FIG. 3 is an exploded view illustrating the fastening device shown in FIG. 2.

FIG. 4 is a perspective view illustrating two storage devices accommodated in the fastening device shown in FIG. 1.

FIG. 5 is an exploded view illustrating the fastening device, two storage devices and the fastening members shown in FIG. 4.

FIG. 6 is an exploded view illustrating the fastening device, two storage devices and the fastening members shown in FIG. 4 from another viewing angle.

### DETAILED DESCRIPTION

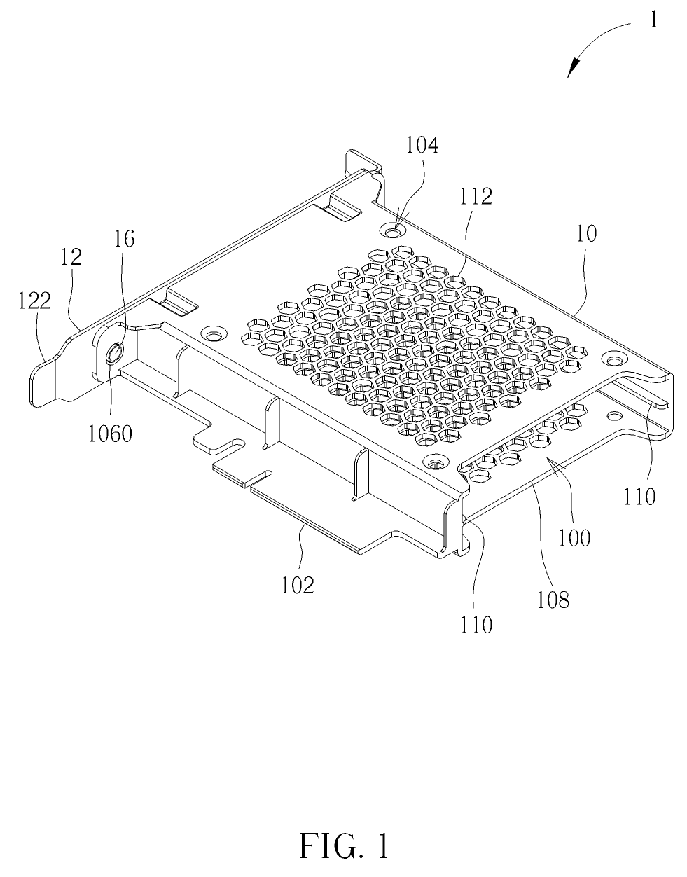

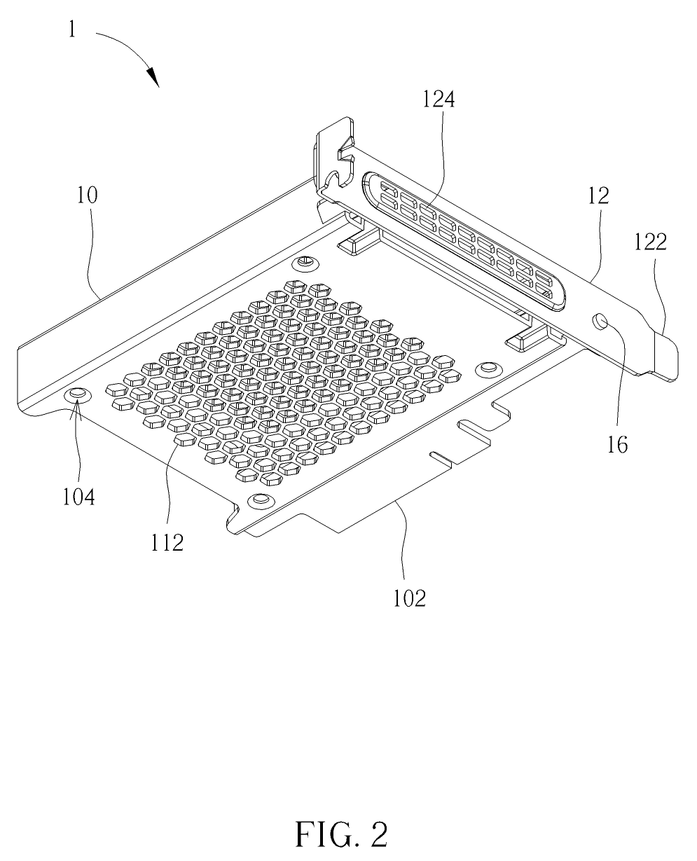

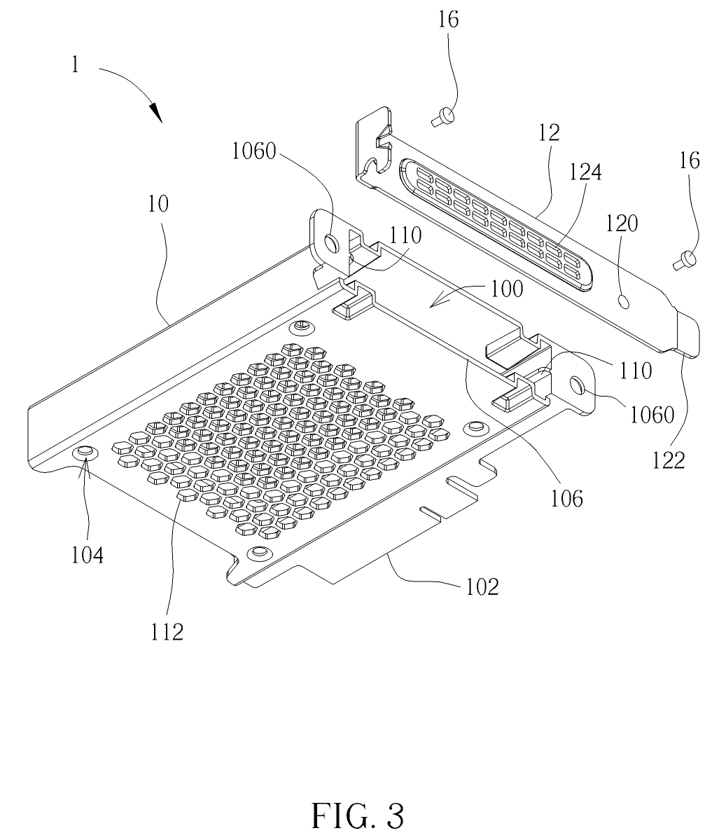

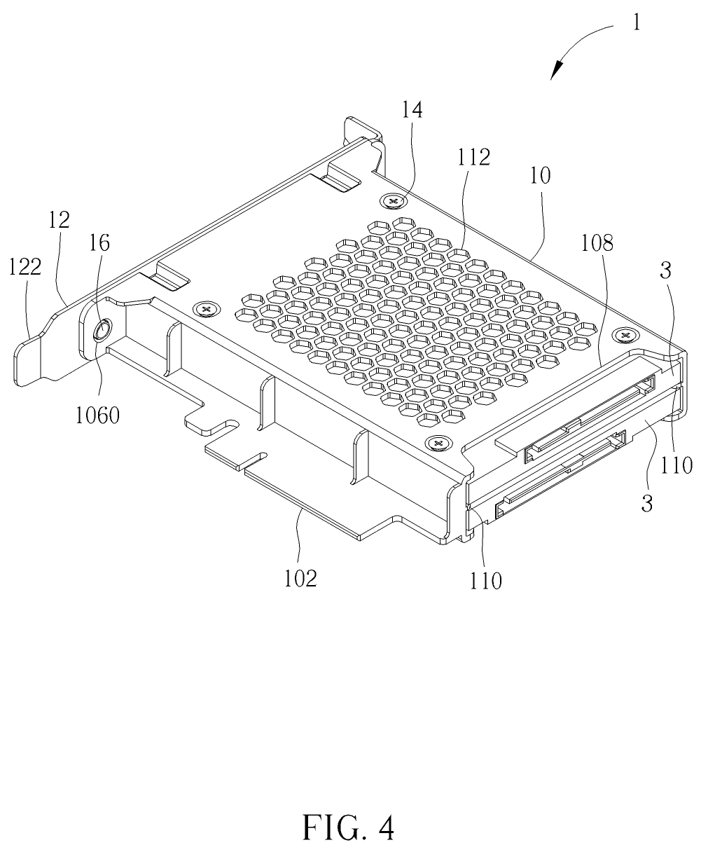

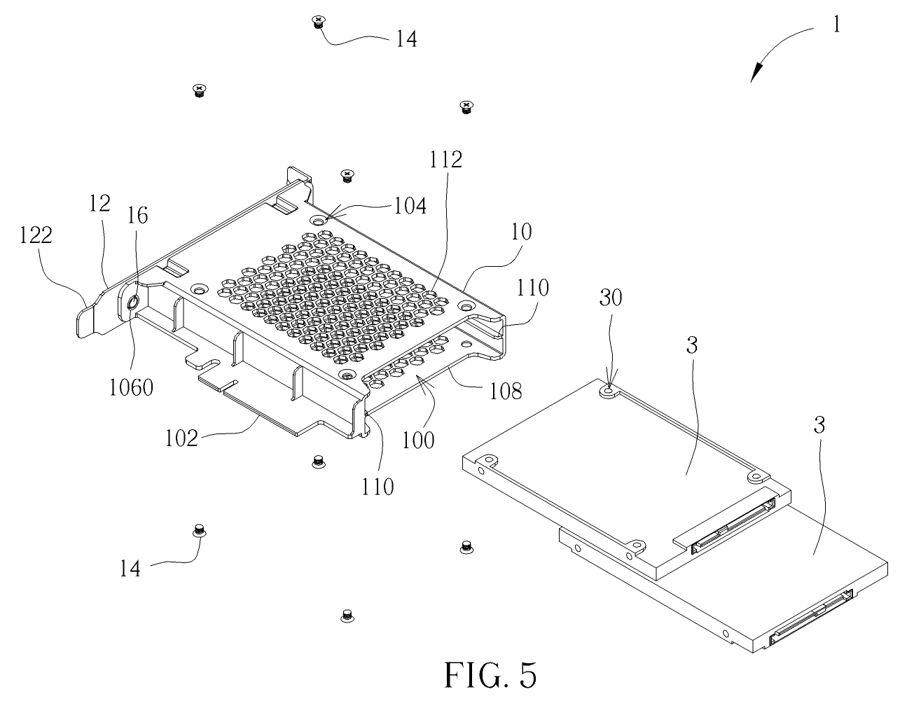

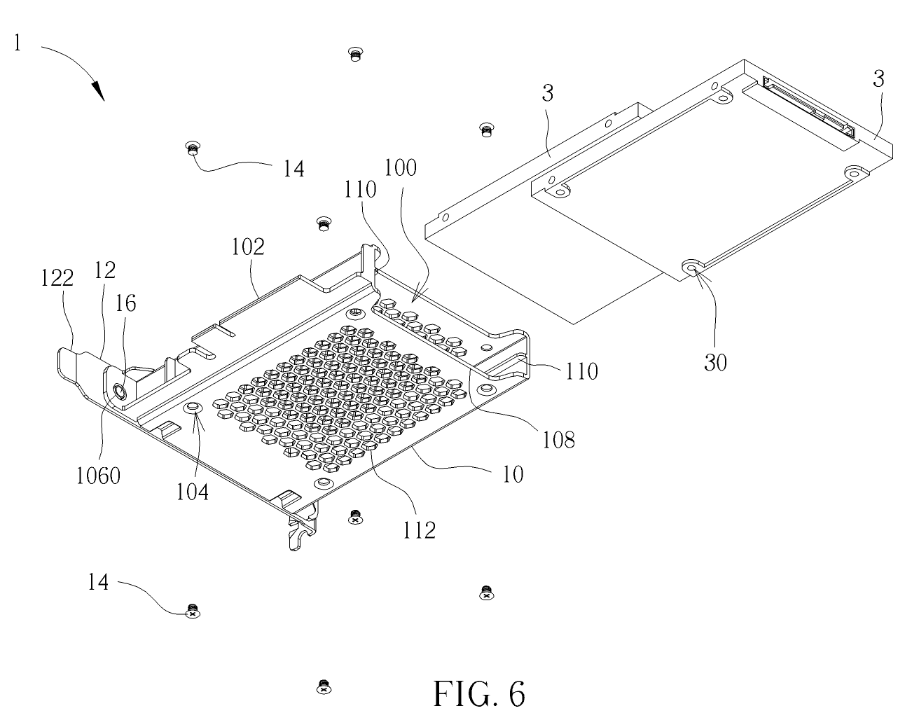

Referring to FIGS. 1 to 6, FIG. 1 is a perspective view illustrating a fastening device 1 according to an embodiment of the invention, FIG. 2 is a perspective view illustrating the fastening device 1 shown in FIG. 1 from another viewing angle, FIG. 3 is an exploded view illustrating the fastening device 1 shown in FIG. 2, FIG. 4 is a perspective view illustrating two storage devices 3 accommodated in the fastening device 1 shown in FIG. 1, FIG. 5 is an exploded view illustrating the fastening device 1, two storage devices 3 and the fastening members 14 shown in FIG. 4, and FIG. 6 is an exploded view illustrating the fastening device 1, two storage devices 3 and the fastening members 14 shown in FIG. 4 from another viewing angle.

As shown in FIGS. 1 to 3, the fastening device 1 comprises a bracket 10 and a cover plate 12. The bracket 10 has an accommodating space 100, a first opening 106 and a second opening 108. In this embodiment, the bracket 10 is formed as a hollow rectangular structure. Furthermore, an assembly rail 110 is disposed at opposite inner side walls of the bracket 10. The cover plate 12 is disposed on a side of the bracket 10 and covers the first opening 106 of the bracket 10. The bracket 10 and the cover plate 12 are engaged with each other, such that an appearance of the fastening device 1 conforms to Peripheral Component Interconnect (PCI) standard. It should be noted that the PCI standard mentioned in the invention also comprises Peripheral Component Interconnect Express (PCIe) standard.

In this embodiment, the first opening 106 of the bracket 10 may extend outwardly to form two connecting portions 1060 at a periphery of the first opening 106. When the cover plate 12 covers the first opening 106, the cover plate 12 is positioned with the first opening 106 by the two connecting portions 1060. In this embodiment, the two connecting portions 1060 may be screw holes. Accordingly, the invention may insert two screws 16 into the two connecting portions 1060 and two corresponding holes 120 of the cover plate 12, so as to fasten the bracket 10 and the cover plate 12. It should be noted that the invention may also fasten the cover plate 12 on the first opening 106 of the bracket 10 by rivet, welding, engagement or other fastening manners.

Furthermore, an outer side wall of the bracket 10 has a connector 102 and the connector 102 is capable of being inserted into a slot (not shown) conforming to PCI standard. In this embodiment, the bracket 10 may be made of plastic. Accordingly, when the connector 102 of the bracket 10 is inserted into the slot conforming to PCI standard, a short circuit will not occur between the connector 102 of the bracket 10 and the electric contacts of the slot.

An end of the cover plate 12 extends to form a guiding portion 122 and a width of the cover plate 12 extending from the end to the guiding portion 122 decreases gradually. In practical applications, the cover plate 12 can be engaged with an external connecting rail (not shown) by the guiding portion 122. The external connecting rail may be disposed on a casing of a computer or a server according to practical applications. When the cover plate 12 is engaged with the external connecting rail by the guiding portion 122, the guiding portion 122 can guide the connector 102 of the bracket 10 to move toward the slot conforming to PCI standard, so as to insert the connector 102 of the bracket 10 into the slot conforming to PCI standard well.

As shown in FIGS. 4 to 6, the fastening device 1 further comprises a plurality of fastening members 14. In this embodiment, the fastening members 14 may be, but not limited to, screws. At least one storage device 3 may be accommodated in the accommodating space 100 through two sides of the assembly rail 110 of the bracket 10. In other words, the accommodating space 100 of the bracket 10 is used for accommodating at least one storage device 3 and the storage device 3 can be placed into or taken out of the accommodating space 100 through the second opening 108 of the bracket 10 by a user. In this embodiment, the accommodating space 100 of the bracket 10 may accommodate two storage devices 3. When the storage device 3 is accommodated in the accommodating space 100 of the bracket 10, the fastening members 14 can fasten the storage device 3 in the bracket 10. In this embodiment, the invention inserts four fastening members 14 into four holes 104 at four corners of the bracket 10 and four corresponding holes 30 at four corners of the storage device 3, so as to fasten the storage device 3. The storage device 3 may be a hard disk drive (HDD) or a solid state drive (SSD) according to practical applications.

In this embodiment, a plurality of holes 112 are formed on opposite surfaces of the bracket 10 and a plurality of holes 124 are formed on the cover plate 12. The holes 112, 124 are arranged densely, so as to dissipate heat within the accommodating space 100 of the bracket 10.

When the capacity of the existing storage device is not enough and the number of storage devices has to be expanded, a user can place the storage device 3 into the bracket 10 of the fastening device 1 of the invention and then use the fastening members 14 to fasten the storage device 3 in the bracket 10. Then, the user can insert the connector 102 of the bracket 10 into the slot conforming to PCI standard. Afterward, the user can fasten the cover plate 12 on a casing of a computer or server (not shown) by screws or other fastening members (not shown). Accordingly, the user can install and expand the storage device easily. Since the bracket 10 of the invention may be made of plastic, a short circuit will not occur between the connector 102 of the bracket 10 and the electric contacts of the slot. Furthermore, since the connector 102 of the bracket 10 can be fastened in the slot by an engaging manner, the invention need not use additional device or structure to fasten the fastening device 1.

In general, a mainboard of the computer or server usually has a plurality of PCI expansion slots for installing a plurality of expansion cards such as sound card, graphics card, network card and so on, so as to enhance additional functions. Since the appearance of the fastening device 1 of the invention conforms to PCI standard, the user can use the fastening device 1 of the invention to accommodate at least one storage device 3 to expand the storage device when there is an idle PCI expansion slot in the computer or server. Accordingly, as long as a system supports PCI interface, the fastening device 1 of the invention can be used to expand the storage device. The use of the invention is wide and the assembly process is easy.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fastening device for fastening at least one storage device, the fastening device comprising:
a bracket having an accommodating space, a first opening and a second opening, the bracket being formed as a hollow rectangular structure, an assembly rail being disposed at opposite inner side walls of the bracket, the at least one storage device being accommodated in the accommodating space through two sides of the assembly rail; and
a cover plate disposed on a side of the bracket and covering the first opening of the bracket, the bracket and the cover plate being engaged with each other, such that an appearance of the fastening device conforms to Peripheral Component Interconnect (PCI) standard.

2. The fastening device of claim 1, further comprising a plurality of fastening members, wherein the plurality of fastening members fasten the storage device in the bracket when the at least one storage device is accommodated in the accommodating space.

3. The fastening device of claim 1, wherein an outer side wall of the bracket has a connector and the connector is capable of being inserted into a slot conforming to PCI standard.

4. The fastening device of claim 1, wherein a plurality of holes are formed on opposite surfaces of the bracket and arranged densely, so as to dissipate heat within the accommodating space.

5. The fastening device of claim 1, wherein the first opening of the bracket extends outwardly to form two connecting portions at a periphery of the first opening, and the cover plate covers the first opening and is positioned with the first opening by the two connecting portions.

6. The fastening device of claim 5, wherein the two connecting portions are screw holes, and the bracket and the cover plate are fastened by the two connecting portions and two screws.

7. The fastening device of claim 1, wherein an end of the cover plate extends to form a guiding portion, a width of the cover plate extending from the end to the guiding portion decreases gradually, such that the guiding portion is capable of being engaged with an external connecting rail.

8. The fastening device of claim 1, wherein an outer side wall of the bracket has a connector, the connector is capable of being inserted into a slot conforming to PCI standard, an end of the cover plate extends to form a guiding portion, a width of the cover plate extending from the end to the guiding portion decreases gradually, such that the guiding portion is capable of being engaged with an external connecting rail, so as to insert the connector into the slot well.

9. The fastening device of claim 1, wherein a plurality of holes are formed on the cover plate and arranged densely, so as to dissipate heat within the accommodating space.

10. The fastening device of claim 1, wherein the accommodating space is used for accommodating the at least one storage device and the at least one storage device is placed into or taken out of the accommodating space through the second opening.
